(19) United States
(12) Patent Application Publication
(10) Pub. No.: US 2016/0225641 A1
(43) Pub. Date: Aug. 4, 2016

(54) DEFECT REDUCTION IN III-V SEMICONDUCTOR EPITAXY THROUGH CAPPED HIGH TEMPERATURE ANNEALING

(71) Applicant: International Business Machines Corporation, Armonk, NY (US)

(72) Inventors: Stephen W. Bedell, Wappingers Falls, NY (US); John A. Ott, Greenwood Lake, NY (US); Devendra K. Sadana, Pleasantville, NY (US); Brent A. Wacaser, Putnam Valley, NY (US); Min Yang, Yorktown Heights, NY (US)

(21) Appl. No.: 14/608,685

(22) Filed: Jan. 29, 2015

(51) Int. Cl. H01L 21/322; H01L 21/02; H01L 21/324

(52) U.S. Cl. CPC H01L 21/3228; H01L 21/3245; H01L 21/02538; H01L 21/02664

(57) ABSTRACT

A structure and method for reducing defects within a III-V compound semiconductor layer grown epitaxially on a mismatched crystalline substrate is provided. The III-V compound semiconductor layer may be surrounded by a thermally stable layer on its sides and a thermally stable capping layer on its upper surface. Subsequent to epitaxial growth, the III-V compound semiconductor layer may be subjected to high temperature annealing in a pressurized atmosphere of the corresponding Group V material present in the III-V compound semiconductor layer. The thermally stable layer and the capping layer may prevent the evaporation of the Group V material from the III-V compound semiconductor layer, as well as cure and rearrange the crystalline lattice structure of the III-V compound semiconductor layer thereby reducing defect density.

### BACKGROUND

The present invention relates generally to semiconductor devices and more specifically to a structure and method for reducing defects within III-V semiconductor materials epitaxially grown on mismatched crystalline substrates.

With many epitaxially grown III-V semiconductor materials, for example GaAs, annealing at temperatures higher than the growth temperature may be performed after epitaxial growth to annihilate defects and reduce overall defect densities. However, the high temperature annealing may cause problems when one of the III-V materials used to form the epitaxial layer exhibits a high partial vapor pressure. For example, during high temperature annealing, Group V materials, which tend to have higher vapor pressures than Group III materials, may evaporate from the surface of the III-V compound semiconductor layer, leaving droplets of Group III material behind. Such decomposition of the III-V compound semiconductor layer may lead to pitting of the III-V compound semiconductor layer. This pitting may negatively affect the integrity of layers formed on top of the III-V compound semiconductor layer, such as a gate dielectric. The defects in the III-V compound semiconductor layer, and subsequent layers, may degrade the performance of the semiconductor device.

The evaporation of the Group V material is typically mitigated by providing an atmosphere of the corresponding Group V material vapor within the annealing chamber during the annealing. However, as the temperature increases during the annealing process, so does the partial pressure of the Group V material within the III-V compound semiconductor layer. When the partial pressure of the Group V material is increased with temperature, it may begin to evaporate regardless of atmospheric Group V material. This may result in a practical upper annealing temperature limit much lower than what is desired.

### SUMMARY

According to an embodiment, a method of protecting an epitaxially grown III-V compound semiconductor layer during high temperature annealing is provided. The method may include: forming thermally stable layer may adjacent to and contacting side surfaces of the III-V compound semiconductor layer; and forming a capping layer on an upper surface of the III-V compound semiconductor layer.

In another embodiment, a method of reducing defects in an epitaxially grown III-V compound semiconductor layer is provided. The method may include: forming a thermally stable layer on a substrate; forming an opening in the thermally stable layer, the opening exposing an upper surface of the substrate; epitaxially growing a III-V compound semiconductor layer on the upper surface of the substrate in the opening, the III-V compound semiconductor layer having an upper portion extending above an upper surface of the thermally stable layer; removing the upper portion of the III-V compound semiconductor layer, such that an upper surface of the III-V compound semiconductor layer is substantially flush with the upper surface of the thermally stable layer; forming a capping layer on the upper surface of the III-V compound semiconductor layer and the upper surface of the thermally stable layer; and annealing the III-V compound semiconductor layer, wherein the capping layer and the thermally stable layer prevent evaporation of Group V material from the III-V compound semiconductor layer.

In another embodiment, a method of reducing defects in an epitaxially grown III-V compound semiconductor layer is provided. The method may include: forming a thermally stable layer on a substrate; forming an opening in the thermally stable layer, the opening exposing an upper surface of the substrate; epitaxially growing a III-V compound semiconductor layer on the upper surface of the substrate in the opening, the III-V compound semiconductor layer having an upper portion extending above an upper surface of the thermally stable layer; removing the upper portion of the III-V compound semiconductor layer, such that an upper surface of the III-V compound semiconductor layer is substantially flush with the upper surface of the thermally stable layer; forming a capping layer on the upper surface of the III-V compound semiconductor layer and the upper surface of the thermally stable layer; and annealing the III-V compound semiconductor layer in an atmosphere of gaseous Group V material found in the III-V compound semiconductor layer, wherein the capping layer and the thermally stable layer prevent evaporation of Group V material from the III-V compound semiconductor layer, and wherein the gaseous Group V material diffuses into the III-V compound semiconductor layer.

### BRIEF DESCRIPTION OF THE SEVERAL VIEWS OF THE DRAWINGS

The following detailed description, given by way of example and not intended to limit the invention solely thereto, will best be appreciated in conjunction with the accompanying drawings, in which not all structures may be shown.

FIG. 1 is a cross section view of illustrating forming a thermally stable layer on a substrate, according to an embodiment of the present invention.

FIG. 2 is a cross section view of illustrating forming an opening in the thermally stable layer, according to an embodiment of the present invention.

FIG. 3 is a cross section view illustrating epitaxially growing a III-V compound semiconductor layer, according to an embodiment of the present invention.

FIG. 4 is a cross section view illustrating removing an upper portion of the III-V compound semiconductor layer, according to an embodiment of the present invention.

FIG. 5 is a cross section view illustrating depositing a capping layer on the III-V compound semiconductor layer, according to an embodiment of the present invention.

FIG. 6 is a cross section view illustrating performing a high temperature capped anneal, according to an embodiment of the present invention.

FIG. 7 is a cross section view illustrating removing the capping layer, according to an embodiment of the present invention.

The drawings are not necessarily to scale. The drawings are merely schematic representations, not intended to portray specific parameters of the invention. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art.

In the following description, numerous specific details are set forth, such as particular structures, components, materials, dimensions, processing steps, and techniques, in order to provide a thorough understanding of the present invention. However, it will be appreciated by one of ordinary skill of the art that the invention may be practiced without these specific details. In other instances, well-known structures or processing steps have not been described in detail in order to avoid obscuring the invention. It will be understood that when an element as a layer, region, or substrate is referred to as being “on” or “over” another element, it can be directly on the other element or intervening elements may also be present. In contrast, when an element is referred to as being “directly on” or “directly” over another element, there are no intervening elements present. It will also be understood that when an element is referred to as being “beneath,” “below,” or “under” another element, it can be directly beneath or under the other element, or intervening elements may be present. In contrast, when an element is referred to as being “directly beneath” or “directly under” another element, there are no intervening elements present.

As used herein, the term “III-V compound semiconductor” denotes a semiconductor material that includes at least one element from Group III of the Periodic Table of Elements (B, Al, Ga, In) and at least one element from Group V of the Periodic Table of Elements (N, P, As, Sb, Bi). Typically, the III-V compound semiconductors may be binary alloys, ternary alloys, or quaternary alloys of III-V elements. Examples of III-V compound semiconductors that can be used in the present invention include, but are not limited to GaAs, InAs, InP, InGaAs, InAlAs, InAlAsSb, InAlAsP, AlInGaP, InGaAsP, and alloys thereof. As used herein, “epitaxy” refers to the deposition of a crystalline overlayer on a crystalline substrate, while “heteroepitaxy” refers specifically to epitaxy performed with materials that are different from each other. Heteroepitaxy implies that although the materials and crystal structures may not be identical, the crystal structures are related, with the substrate or underlying layer templating the crystal structure of the overlayer.

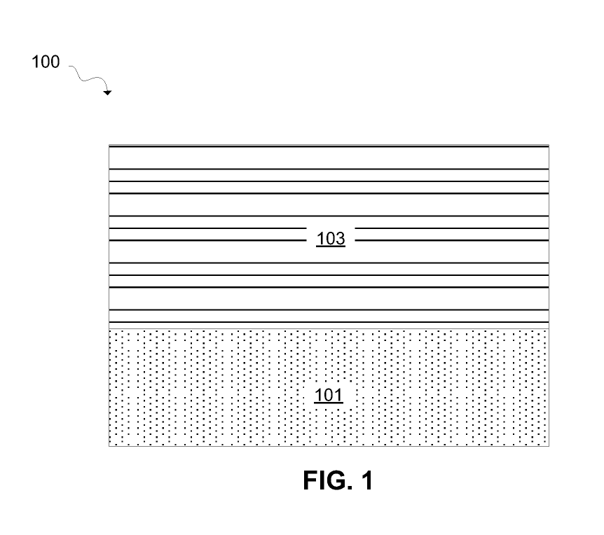

Embodiments of the present invention relate generally to heteroepitaxial growth of semiconductor layers, and more particularly to a structure and method for reducing defects within a III-V compound semiconductor layer by surrounding the III-V semiconductor layer with a thermally stable material during high temperature annealing. Embodiments by which to fabricate III-V compound semiconductor layers having a lower defect density than those grown using techniques currently known in the art are described in detail below with reference to FIGS. 1-7.

Referring now to FIG. 1, a possible starting point of a capped high temperature anneal process is shown. A preliminary structure 100 may be formed by depositing a thermally stable layer 103 on a substrate 101. The substrate 101 may be made of any semiconductor material typically known in the art, including, for example, silicon, germanium, silicon-germanium alloy, silicon carbide, silicon-germanium carbide alloy, and compound (e.g. II-VI) semiconductor materials. In an embodiment, the substrate 101 may be a bulk substrate. In another embodiment, the substrate 101 may be a semiconductor on insulator (SOI) substrate. In a preferred embodiment, the substrate 101 is composed of silicon.

The thermally stable layer 103 may be formed on an upper surface of the substrate 101 using a conventional deposition technique, such as, for example, molecular beam epitaxy (MBE), chemical vapor deposition (CVD), plasma enhanced CVD (PECVD), atomic layer deposition (ALD), evaporation, physical vapor deposition (PVD), chemical solution deposition, and other like deposition processes. The thermally stable layer 103 may be composed of a low-k dielectric material including, but not limited to, an oxide and/or a silicate. A “low-k” material may be a dielectric material with a lower dielectric constant relative to silicon dioxide (SiO₂), which is 3.9 (i.e., the ratio of the permittivity of SiO₂ divided by the permittivity of a vacuum). The thermally stable layer 103 may be porous or non-porous. In an embodiment, the thermally stable layer 103 may be composed of an interlevel or intralevel dielectric material, including inorganic dielectrics and organic dielectrics. In another embodiment, the thermally stable layer 103 may be composed of silicon coated with a thin layer of SiO₂.

The thickness of the thermally dielectric layer 103 may vary depending upon the material that it is composed of. In an embodiment, the thermally stable layer 103 may have a thickness ranging between approximately 100 nm and approximately 9000 nm. In a preferred embodiment, the thermally stable layer 103 may have a thickness ranging from approximately 200 nm to approximately 3000 nm. In an embodiment, the thermally stable layer 103 material may be planarized after it is deposited using a conventional technique such as, for example, chemical mechanical planarization (CMP).

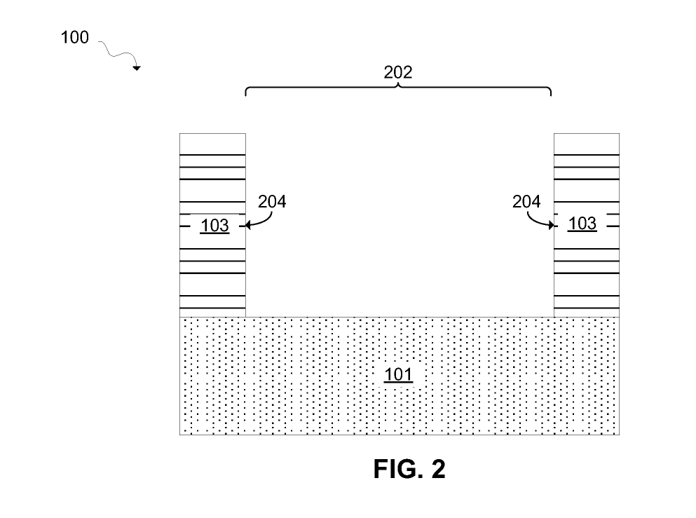

Referring now to FIG. 2, a cross section view illustrating forming an opening 202 in the thermally stable layer 103 is shown. The opening 202 may be formed using conventional lithographic and etching techniques. In an embodiment, a photoresist material (not shown) may be formed on an upper surface of the thermally stable layer 103. The photoresist material may then be patterned by a photolithography process to provide a photoresist pattern. After the photoresist material is patterned, a portion of the thermally stable layer 103 may be removed using a conventional etching process to form the opening 202. The etching process may be performed in one or more steps. In an embodiment, the etching process may include a dry etching process such as reactive ion etching (RIE), ion beam etching, or plasma etching. The patterned photoresist may be removed after the opening 202 is formed. The opening 202 may expose an upper surface of the substrate 101 and may be defined by vertical sidewalls 204 of the thermally stable layer 103. In an embodiment, the opening 202 may have a depth ranging from approximately 200 nm to approximately 3000 nm.

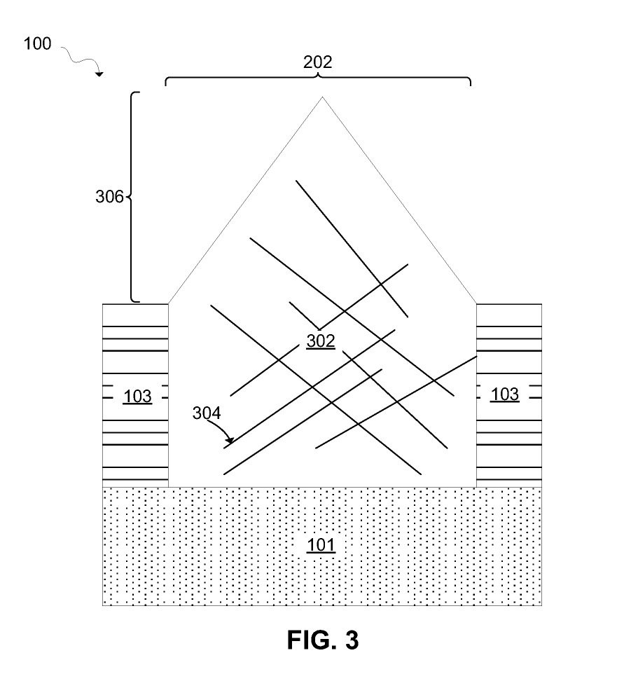

Referring now to FIG. 3, a cross section view illustrating forming a III-V compound semiconductor layer 302 in the opening 202 is shown. The III-V compound semiconductor layer 302 may be heteroepitaxially grown on the upper surface of the substrate 101 using techniques well known in the art. In an embodiment, the III-V compound semiconductor layer 302 may be formed using, for example, epitaxial lateral overgrowth (ELOG), metal organic CVD (MOCVD), metal organic vapor phase epitaxy (MOVPE), plasma enhanced CVD (PECVD), remote plasma enhanced CVD (RP-CVD), molecular beam epitaxy (MBE), hydride vapor phase epitaxy (HVPE), chloride vapor phase epitaxy (Cl-VPE), or liquid phase epitaxy (LPE). In an embodiment, the III-V compound semiconductor layer 302 may be grown such that an upper portion 306 extends above the opening 202.

The III-V compound semiconductor layer 302 may be composed of a III-V semiconductor material including, but not limited to GaSb, GaP, GaAs, InAs, InP, and alloys thereof. In an embodiment, the III-V compound semiconductor layer 201 may be a binary compound material, for e.g., GaAs. The III-V compound semiconductor 302 may be doped, undoped or contain doped and undoped regions therein. The III-V compound semiconductor 302 may have a single crystal orientation, or may have surface regions that have different crystal orientations. The III-V compound semiconductor layer 302 may be strained, unstrained or a combination thereof. In an embodiment, a graded III-V compound semiconductor layer may be formed.

In an embodiment, the epitaxially grown III-V compound semiconductor layer 302 may be of typical commercial quality, an may include defects 304 in the crystalline lattice. The III-V compound semiconductor layer 302 may have a defect density on the order of about 10⁵ defects/cm² or less, with a defect density of less than about 5000 defects/cm² being preferred. In an embodiment, the III-V compound semiconductor layer 302 may consist of III-V material that may crystallize at a certain temperature, for example, of about 400° C., forming a single or multi crystalline structure, as compared to the more amorphous structure. The defects 304 formed within the III-V compound layer 302 may be spread throughout the entire crystalline lattice structure.

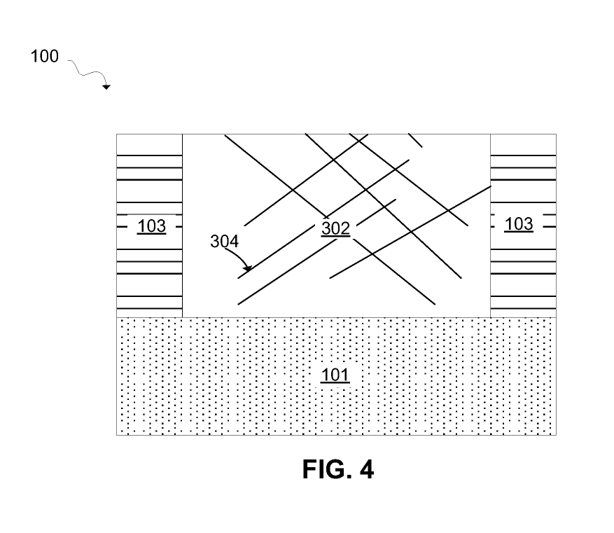

Referring now to FIG. 4, a cross section view illustrating removing the upper portion 306 (FIG. 3) of the III-V compound semiconductor layer 302 is shown. The removal of the upper portion 306 may provide a surface that is flush with the thermally stable layer 103 and suitable for subsequent processing. The upper portion 306 may be removed by a conventional planarization technique, such as, a recess etch, chemical mechanical planarization (CMP), or a combination thereof. In an embodiment, a portion of the thermally stable layer 103 may also be removed during the planarization process. After the removal, an upper surface of the thermally stable layer 103 may be substantially flush with an upper surface of the III-V compound semiconductor layer 302.

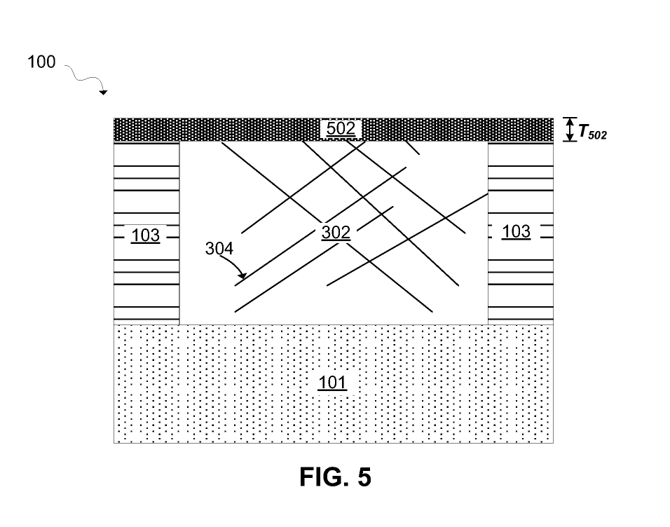

Referring now to FIG. 5, a cross section view illustrating forming a capping layer 502 on the upper surface of the III-V compound semiconductor layer 302 and the upper surface of the thermally stable layer 103 is shown. The capping layer 502 may consist of a thermally stable material and may act as a passivating layer for the III-V compound semiconductor layer 302. In an embodiment, the capping layer 502 may be composed of a material that is substantially similar to the material of the thermally stable layer 103. In another embodiment, the capping layer 502 may be composed of silicon nitride, aluminum oxide, silicon dioxide, or other similar materials. The capping layer 502 may also include carbon, hydrogen, or nitrogen atoms.

The capping layer 502 may be formed utilizing any conventional deposition process including, but not limited to, plasma enhanced chemical vapor deposition (PECVD), microwave enhanced chemical vapor deposition (MECVD), chemical vapor deposition (CVD), atomic layer deposition (ALD), e-beam evaporation, and sputtering.

In an embodiment, the capping layer 502 may be formed using a silicon-containing process gas, such as for example, silane (SiH₄), disilane, dichlorosilane, trichlorosilane, and tetraethylorthosilane, methylsilane (CH₃SiH₃), dimethylsilane ((CH₃)₂SiH₂), trimethylsilane ((CH₃)₃SiH), diethylsilane ((C₂H₅)₂SiH₂), propylsilane (C₃H₈SiH₃), vinyl methylsila (CH₂═CH)CH₃SiH₂), 1,1,2,2-tetramethyl disilane (HSi(CH₃)₂—Si(CH₃)₂H), hexamethyl disilane ((CH₃)₃Si—Si(CH₃)₃), 1,1,2,2,3,3-hexamethyl trisilane (H(CH₃)₂Si—Si(CH₃)₂—SiH(CH₃)₂), 1,1,2,3,3-pentamethyl trisilane (H(CH₃)₂Si—SiH(CH₃)—SiH(CH₃)₂), or other silane related compounds. The silicon-containing process gas may be mixed with an oxygen-containing process gas, such as oxygen (O₂), nitrous oxide (N₂O), ozone (O₃), or carbon dioxide (CO₂). In a preferred embodiment, the capping layer 502 may be formed by depositing silicon dioxide using e-beam evaporation and then annealing the structure 100 at approximately 900° C. for approximately 5 seconds.

The thickness of the capping layer 502 may vary depending on the deposition technique employed. In an embodiment, the capping layer 502 may have a thickness T₅₀₂ ranging from approximately 0.2 nm to approximately 500 nm, with a thickness T₅₀₂ ranging from approximately 10 nm to 200 nm being preferred. In an embodiment, the thickness T₅₀₂ of the capping layer 502 may be sufficient to allow for the capping layer 502 to act as capping/passivating layer that, along with the thermally stable layer 103, may protect the III-V compound semiconductor layer 302 during a high temperature anneal.

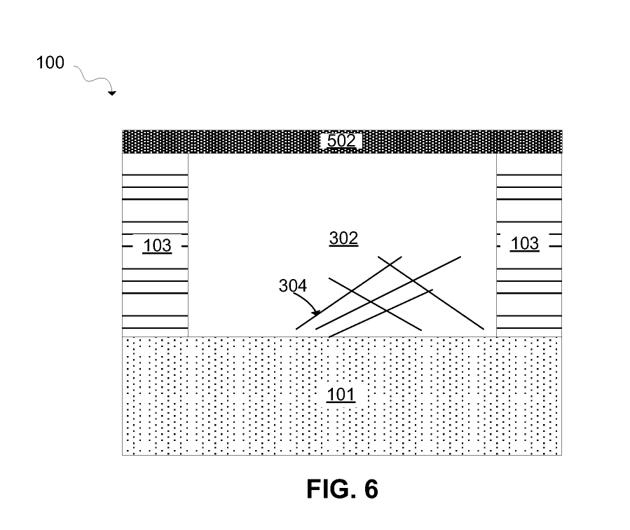

Referring now to FIG. 6, a cross section view illustrating performing a high temperature annealing process on the structure 100 is shown. The structure 100 may be subjected to a conventional annealing processes, such as, for example, rapid thermal annealing (RTA), flash lamp annealing, furnace annealing, laser annealing, and combinations thereof. The annealing process may include one or more steps. During the annealing process, the structure 100 may be heated to a temperature ranging from approximately 500° C. to approximately 2000° C., with a temperature ranging from approximately 600° C. to approximately 850° C. being preferred. In an embodiment, the annealing process may be carried out for a time period ranging from approximately 1 second to approximately 300 seconds. The capping layer 502 and the thermally stable layer 103 may prevent the evaporation of the Group V material from the III-V compound semiconductor layer 302 during the annealing process. This may reduce the number of defects 304 in the III-V compound semiconductor layer 302 by allowing the high temperature anneal to mobilize and annihilate the defects 304 in the crystalline lattice structure without the evaporation of Group V material.

In an embodiment where the III-V compound semiconductor layer 302 is composed of GaN, annealing temperatures of over 1300° C. may be required to completely activate the material and any ion-implanted dopants. Without the capping layer 502, the GaN may decompose into Ga when annealed at temperatures above 800° C. due to nitrogen evaporation. The capping layer 502 may prevent evaporation and migration of nitrogen out of the III-V compound semiconductor layer 302, and the annealing temperature may be raised well above 800° C. without causing surface faceting or decomposition of the III-V compound semiconductor layer 302. In an embodiment, the annealing process may be performed at temperatures of approximately 1300° C. or higher without causing damage to the III-V compound semiconductor layer 302.

In an embodiment, the annealing process may be performed in a pressurized atmosphere of gaseous Group V material corresponding to the Group V material that is present in the III-V compound semiconductor layer 302. The combination of the capping layer 502, the thermally stable layer 103, and the pressurized Group V material atmosphere may not only prevent the Group V material from evaporating out of the III-V compound semiconductor layer 302, but may even result in the atmospheric Group V material diffusing into the III-V compound semiconductor layer 302. This may reduce the number as well as the magnitude of defects 304 in the III-V compound semiconductor layer 302.

In an embodiment where the III-V compound semiconductor layer 302 is composed of GaAs, the high temperature anneal may be performed in an atmosphere of arsenic or arsine at a pressure ranging from approximately 10⁻³ torr to approximately 100 torr. Without the capping layer 502, the highest temperature that could be used for in situ annealing under the same arsenic atmosphere, may be approximately 700° C. This practical limit is approximately 50° C. above the congruent temperature for GaAs sublimation (i.e., the temperature at which the vapor pressures of the gallium and arsenic are equal). However, because the capping layer 502 may prevent evaporation and migration of the As out of the III-V compound semiconductor layer 302, the annealing temperature may be raised well above 700° C. without causing surface faceting or decomposition of the III-V semiconductor layer 302. In an embodiment, the capped annealing process, when performed in atmospheric As, may be performed at temperatures of approximately 800° C. or higher without causing damage to the III-V compound semiconductor layer 302.

The capping layer 502 may prevent the evaporation and movement of Group V atoms out of the III-V compound semiconductor layer 302 during high temperature annealing. The capping layer 502 and the sidewalls 204 (FIG. 2) of the thermally stable layer 103 may serve as a barrier to evaporation and may exert pressure on the III-V compound semiconductor layer 302, thereby increasing the partial pressure of the Group V material. During high temperature annealing, the mismatch in thermal expansion between the Group III and Group V elements within the III-V compound semiconductor layer 302 may increase strain and stress within the III-V compound semiconductor layer 302. The capping layer 502 and the thermally stable layer 103 may prevent the relief of this strain and stress through faceting or by expansion upward, which may occur during conventional annealing techniques. As a result, the potential energy of the stress and strain may rearrange and cure the crystalline structure within the III-V compound semiconductor layer 302, and reduce the number as well as the magnitude of defects 304.

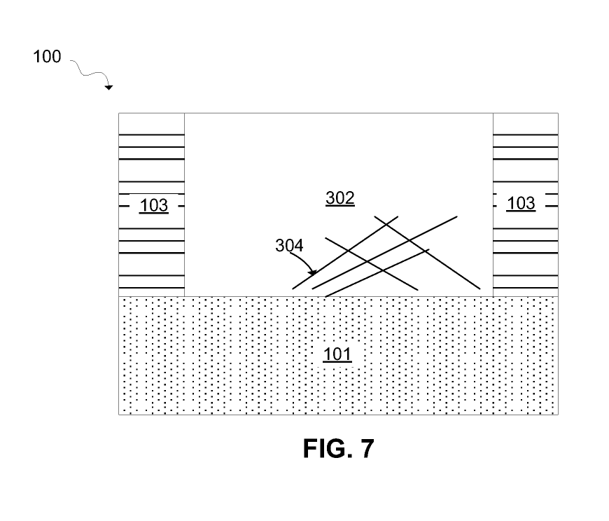

Referring now to FIG. 7, a cross section view illustrating removing the capping layer 502 (FIG. 6) after annealing is completed is shown. In an embodiment, the capping layer 502 may be removed through a conventional etching process, such as, for example, a wet etch or a stripping process. In another embodiment, the capping layer 502 may be removed using a conventional planarization process, such as, for example, CMP. After removing the capping layer 502, the III-V compound semiconductor layer 302 may be further processed. For example, a gate conductor (not shown) may be formed on the upper surface of the III-V compound semiconductor layer 302 by a conventional deposition process such as, for example, CVD, PECVD, PVD, plating, thermal or ebeam evaporation and sputtering.

Embodiments of the current invention may reduce defects present within a III-V compound semiconductor layer by surrounding the III-V compound semiconductor layer with thermally stable material during a high temperature annealing process. In an embodiment, a III-V compound semiconductor layer may be grown in an opening of a thermally stable layer and then capped with a thermally stable capping layer. The thermally stable material may prevent the evaporation of high vapor pressure Group V material out of the III-V compound semiconductor layer during the high temperature anneal and may reduce the defect density within the layer. In an embodiment, the high temperature annealing may be performed in a pressurized atmosphere containing the Group V element, allowing the migration of the Group V material into the III-V compound semiconductor layer to reduce defect density. The curing and rearrangement of the crystalline lattice structure of the III-V semiconductor layer that may result from the capped annealing may help reduce surface faceting and surface decomposition. This may improve the III-V semiconductor material's dielectric properties. The capped annealing process may also render the surface of the III-V compound semiconductor material in excellent condition for further processing, such as re-growth, without requiring additional preparation requirements.

The terminology used herein is for the purpose of describing particular embodiments only and is not intended to be limiting of the invention. As used herein, the singular forms “a,” “an,” and “the” are intended to include the plural forms as well, unless the context clearly indicates otherwise. The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A method of protecting an epitaxially grown III-V compound semiconductor layer during high temperature annealing comprising:
forming a thermally stable layer adjacent to and contacting side surfaces of the III-V compound semiconductor layer; and
forming a capping layer on an upper surface of the III-V compound semiconductor layer.

2. The method of claim 1 wherein the high temperature annealing is performed in an atmosphere of gaseous Group V material found in the III-V compound semiconductor layer.

3. The method of claim 1 wherein the thermally stable layer comprises silicon surrounded by a layer of silicon dioxide.

4. The method of claim 1 wherein the capping layer has a thickness ranging from approximately 10 nm to approximately 200 nm.

5. The method of claim 1 wherein the capping layer comprises a nitride.

6. A method of reducing defects in an epitaxially grown III-V compound semiconductor layer comprising:
forming a thermally stable layer on a substrate;
forming an opening in the thermally stable layer, the opening exposing an upper surface of the substrate;
epitaxially growing a III-V compound semiconductor layer on the upper surface of the substrate in the opening, the III-V compound semiconductor layer having an upper portion extending above an upper surface of the thermally stable layer;
removing the upper portion of the III-V compound semiconductor layer, such that an upper surface of the III-V compound semiconductor layer is substantially flush with the upper surface of the thermally stable layer;
forming a capping layer on the upper surface of the III-V compound semiconductor layer and the upper surface of the thermally stable layer; and
annealing the III-V compound semiconductor layer, wherein the capping layer and the thermally stable layer prevent evaporation of Group V material from the III-V compound semiconductor layer.

7. The method of claim 6 wherein the capping layer has a thickness of between approximately 10 nm and approximately 200 nm.

8. The method of claim 6 wherein annealing of the III-V compound semiconductor layer comprises:
heating the III-V compound semiconductor layer to a temperature ranging from approximately 500° C. to approximately 2000° C.

9. The method of claim 6 wherein annealing of the III-V compound semiconductor layer is performed for a time period ranging from approximately 1 second to approximately 300 seconds.

10. The method of claim 6 wherein annealing of the III-V compound semiconductor layer is performed at a pressure ranging from approximately 10⁻³ torr to approximately 100 torr.

11. The method of claim 6 wherein the capping layer comprises silicon nitride, aluminum oxide, or silicon dioxide.

12. The method of claim 6 wherein the thermally stable layer comprises silicon surrounded by a layer of silicon dioxide.

13. The method of claim 6 wherein the opening in the thermally stable layer has a depth ranging from approximately 200 nm to approximately 3000 nm.

14. The method of claim 6 wherein the capping layer comprises the same material as the thermally stable layer.

15. A method of reducing defects in an epitaxially grown III-V compound semiconductor layer comprising:
forming a thermally stable layer on a substrate;
forming an opening in the thermally stable layer, the opening exposing an upper surface of the substrate;
epitaxially growing a III-V compound semiconductor layer on the upper surface of the substrate in the opening, the III-V compound semiconductor layer having an upper portion extending above an upper surface of the thermally stable layer;
removing the upper portion of the III-V compound semiconductor layer, such that an upper surface of the III-V compound semiconductor layer is substantially flush with the upper surface of the thermally stable layer;
forming a capping layer on the upper surface of the III-V compound semiconductor layer and the upper surface of the thermally stable layer; and
annealing the III-V compound semiconductor layer in an atmosphere of gaseous Group V material found in the III-V compound semiconductor layer, wherein the capping layer and the thermally stable layer prevent evaporation of Group V material from the III-V compound semiconductor layer, and wherein the gaseous Group V material diffuses into the III-V compound semiconductor layer.

16. The method of claim 15 wherein the capping layer comprises silicon nitride, aluminum oxide, or silicon dioxide.

17. The method of claim 15 wherein the capping layer has a thickness ranging from approximately 10 nm to approximately 200 nm.

18. The method of claim 15 wherein annealing of the III-V compound semiconductor layer comprises:
heating the III-V compound semiconductor layer to a temperature ranging from approximately 500° C. to approximately 2000° C.

19. The method of claim 15 wherein annealing of the III-V compound semiconductor layer is performed at a pressure ranging from approximately 10⁻³ torr to approximately 100 torr.

20. The method of claim 15 wherein the thermally stable layer comprises silicon surrounded by a layer of silicon dioxide.
